(19) United States
(12) Patent Application Publication
(10) Pub. No.: US 2025/0207245 A1
(43) Pub. Date: Jun. 26, 2025

(54) FILM FORMATION METHOD AND FILM FORMATION DEVICE

(71) Applicant: Tokyo Electron Limited, Minato-ku, Tokyo (JP)

(72) Inventors: Tomohiro NAKAGAWA, Nirasaki City, Yamanashi (JP); Yumiko KAWANO, Nirasaki City, Yamanashi (JP); Toru USUKI, Nirasaki City, Yamanashi (JP); Shinichi IKE, Hwaseong-si, Gyeonggi-do (KR); Shuji AZUMO, Nirasaki City, Yamanashi (JP); Yusaku KASHIWAGI, Nirasaki City, Yamanashi (JP)

(21) Appl. No.: 18/849,058

(22) PCT Filed: Mar. 13, 2023
(86) PCT No.: PCT/JP2023/009566

§ 371 Date: Sep. 20, 2024

(30) Foreign Application Priority Data
Mar. 25, 2022 (JP) 2022-049570

(51) Int. Cl. C23C 16/04; C23C 16/455; C23C 16/52; H01L 21/02; H01L 21/311

(52) U.S. Cl. CPC C23C 16/042; C23C 16/45525; C23C 16/52; H01L 21/02337; H01L 21/31111; H01L 21/31133

(57) ABSTRACT

A film forming method includes the following (A) to (F). (A) Preparing a substrate which has a first film and a second film in different regions on a surface thereof. (B) Selectively forming a self-assembled monolayer (SAM) on a surface of the second film using an organic compound that does not contain fluorine. (C) After (B), forming a protective film on a surface of the first film while inhibiting formation of the protective film on the surface of the second film using the SAM. (D) After (C), fluorinating the SAM and the protective film. (E) After (D), etching a fluorinated portion of the protective film. (F) After (E), forming a target film on a surface of the protective film or the surface of the first film while inhibiting the target film from being formed on the surface of the second film using the fluorinated SAM.

### TECHNICAL FIELD

The present disclosure relates to a film forming method and a film forming apparatus.

### BACKGROUND

Patent Document 1 discloses a film forming method in which a self-assembled monolayer (SAM) is used to inhibit a target film (third film) from being formed on a portion of a substrate surface and the target film (third film) is formed on another portion of the substrate surface. In Patent Document 1, an organic compound containing fluorine is used as a precursor of the SAM. After the target film is formed, the SAM is excited by irradiating the target film with at least any one of ions and active species to generate active species containing fluorine and carbon. Then, the active species containing fluorine and carbon react with a side portion of the target film adjacent to the SAM. As a result, the side portion of the target film becomes a volatile compound and is removed.

### PRIOR ART DOCUMENTS

### Patent Documents

Patent Document 1: Japanese Patent Laid-Open Publication No. 2021-44534

One aspect of the present disclosure provides a technique for improving blocking performance of a SAM which does not contain fluorine and suppressing the deterioration of a substrate when improving the blocking performance.

### SUMMARY

According to one embodiment of the present disclosure, a film forming method includes (A) to (F) below. (A) A substrate having a first film and a second film made of a material different from a material of the first film in different regions of a surface of the substrate is prepared. (B) A self-assembled monolayer (SAM) is selectively formed on a surface of the second film with respect to a surface of the first film using an organic compound not containing fluorine. (C) After (B), a protective film is formed on the surface of the first film while inhibiting the protective film from being formed on the surface of the second film using the SAM. (D) After (C), the SAM and the protective film are fluorinated. (E) After (D), a fluorinated portion of the protective film is etched. (F) After (E), a target film is formed on a surface of the protective film or the surface of the first film while inhibiting the target film from being formed on the surface of the second film using the fluorinated SAM.

According to one aspect of the present disclosure, it is possible to improve blocking performance of a SAM which does not contain fluorine and suppress deterioration of a substrate when improving the blocking performance.

### BRIEF DESCRIPTION OF DRAWINGS

FIG. 1 is a flowchart illustrating a film forming method according to an embodiment.

FIG. 2A is a diagram illustrating a first example of step S101.

FIG. 2B is a diagram illustrating a first example of step S102.

FIG. 2C is a diagram illustrating a first example of step S103.

FIG. 2D is a diagram illustrating a first example of step S104.

FIG. 3A is a diagram illustrating a first example of step S105.

FIG. 3B is a diagram illustrating a first example of step S106.

FIG. 3C is a diagram illustrating a first example of step S107.

FIG. 3D is a diagram illustrating a first example of step S109.

FIG. 4A is a diagram illustrating a first example of step S110.

FIG. 4B is a diagram illustrating a modified example of FIG. 4A.

FIG. 5 is a flowchart illustrating an example of a subroutine of step S105.

FIG. 6 is a flowchart illustrating an example of a subroutine of step S109.

FIG. 7 is a flowchart illustrating an example of a subroutine of step S110.

FIG. 8 is a flowchart illustrating an example of processing performed after step S110 in FIG. 1.

FIG. 9A is a diagram illustrating a second example of step S101.

FIG. 9B is a diagram illustrating a second example of step S102.

FIG. 9C is a diagram illustrating a second example of step S103.

FIG. 9D is a diagram illustrating a second example of step S104.

FIG. 10A is a diagram illustrating a second example of step S105.

FIG. 10B is a diagram illustrating a second example of step S106.

FIG. 10C is a diagram illustrating a second example of step S107.

FIG. 10D is a diagram illustrating a second example of step S109.

FIG. 11A is a diagram illustrating a second example of step S110.

FIG. 11B is a diagram illustrating a modified example of FIG. 11A.

FIG. 12A is a diagram illustrating a third example of step S101.

FIG. 12B is a diagram illustrating a third example of step S102.

FIG. 12C is a diagram illustrating a third example of step S103.

FIG. 12D is a diagram illustrating a third example of step S104.

FIG. 13A is a diagram illustrating a third example of step S105.

FIG. 13B is a diagram illustrating a third example of step S106.

FIG. 13C is a diagram illustrating a third example of step S107.

FIG. 13D is a diagram illustrating a third example of step S109.

FIG. 14A is a diagram illustrating a third example of step S110.

FIG. 14B is a diagram illustrating a modified example of FIG. 14A.

FIG. 15 is a plan view illustrating a film forming apparatus according to an embodiment.

FIG. 16 is a cross-sectional view illustrating an example of a first processor in FIG. 15.

### DETAILED DESCRIPTION

Hereinafter, embodiments of the present disclosure will be described with reference to the accompanying drawings. In each drawing, the same or corresponding components are denoted by the same reference numerals, and the description thereof may be omitted.

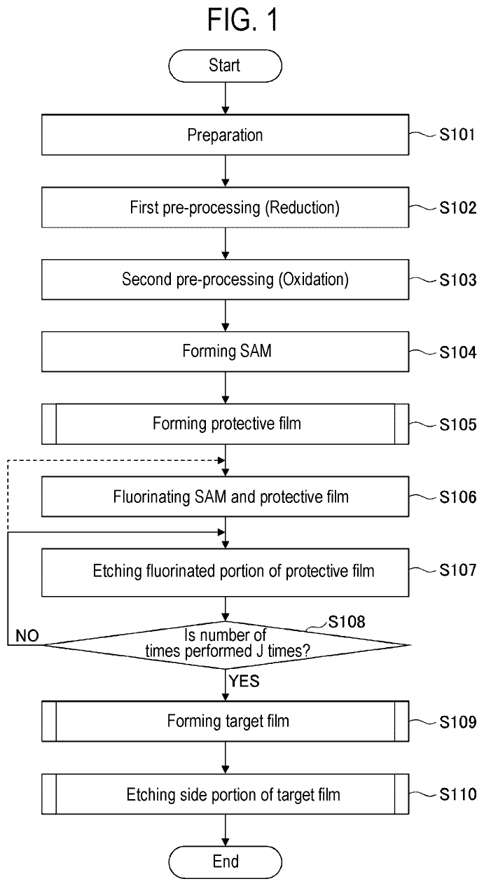

A film forming method according to an embodiment will now be described with reference to FIGS. 1 to 7. The film forming method has, for example, steps S101 to S110 illustrated in FIG. 1. The film forming method may have at least step S101 and steps S104 to S109. For example, the film forming method may not have steps S102 and S103. The film forming method may have steps other than steps S101 to S110 illustrated in FIG. 1.

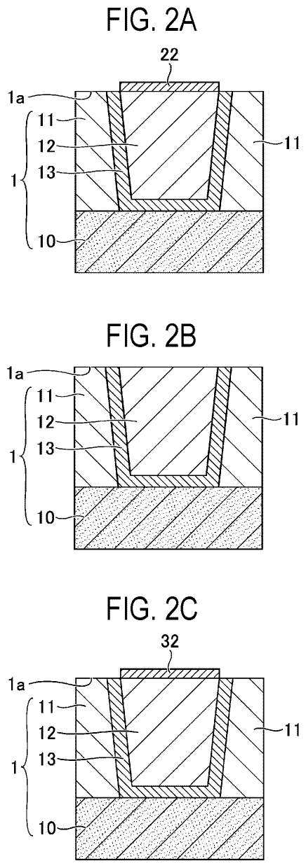

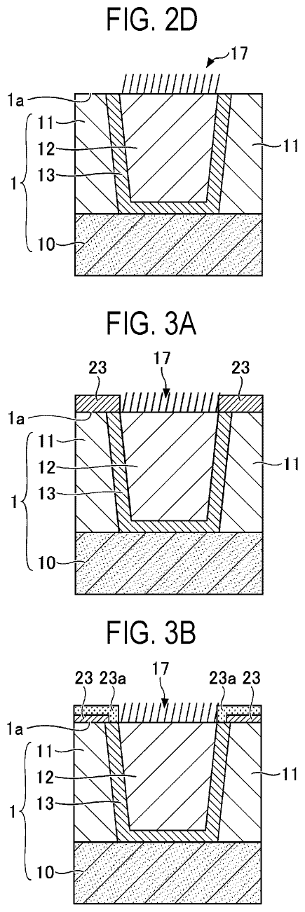

Step S101 in FIG. 1 includes preparing a substrate 1 as illustrated in FIG. 2A. The substrate 1 has a base substrate 10. The base substrate 10 is, for example, a silicon wafer, a compound semiconductor wafer, or a glass substrate. The substrate 1 has an insulating film 11 and a conductive film 12 in different regions of a substrate surface 1a. The substrate surface 1a is, for example, an upper surface of the substrate 1. The insulating film 11 and the conductive film 12 are formed on the base substrate 10. Another functional film may be formed between the base substrate 10 and the insulating film 11 or between the base substrate 10 and the conductive film 12. The insulating film 11 is an example of a first film, and the conductive film 12 is an example of a second film. The materials of the first film and the second film are not particularly limited. The first film may be a conductive film, and the second film may be an insulating film.

The insulating film 11 is, for example, an interlayer insulating film. The interlayer insulating film is desirably a low dielectric constant (low-k) film. The insulating film 11 is, for example, a SiO film, a SiN film, a SiC film, a SiOC film, a SiCN film, a SiON film, or a SiOCN film, but is not particularly limited thereto. Here, the SiO film means a film containing silicon (Si) and oxygen (O). The atomic ratio of Si to O in the SiO film is usually 1:2 but is not limited to 1:2. Similarly, each of the SiN film, the SiC film, the SiOC film, the SiCN film, the SiON film, and the SiOCN film also means a film containing corresponding elements and is not limited to a stoichiometric ratio. The insulating film 11 has a recess on the substrate surface 1a. The recess is a trench, a contact hole, or a via hole.

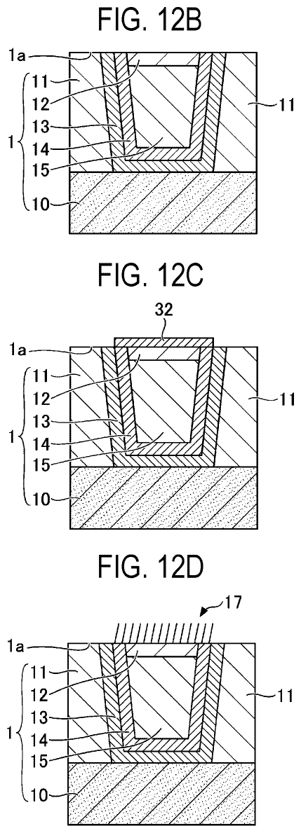

The conductive film 12 is filled, for example, in the recess of the insulating film 11. The conductive film 12 is, for example, a metal film. The metal film is, for example, a Cu film, a Co film, a Ru film, a W film, or a Mo film. The conductive film 12 may be a cap film. In other words, as illustrated in FIG. 12A, a second conductive film 15 may be filled in the recess of the insulating film 11, and the second conductive film 15 may be covered by the conductive film 12. The second conductive film 15 is formed of a metal different from that of the conductive film 12.

The substrate 1 may further have a third film on the substrate surface 1a. The third film is, for example, a barrier film 13. The barrier film 13 is formed between the insulating film 11 and the conductive film 12 and suppresses metal diffusion from the conductive film 12 to the insulating film 11. The barrier film 13 is, for example, a TaN film or a TiN film, but is not particularly limited thereto. Here, the TaN film means a film containing tantalum (Ta) and nitrogen (N). The atomic ratio of Ta to N in the TaN film is usually 1:1 but is not limited to 1:1. Similarly, the TiN film means a film containing corresponding elements and is not limited to a stoichiometric ratio.

Table 1 summarizes specific examples of the insulating film 11, the conductive film 12, and the barrier film 13.

TABLE 1

| Insulating Film | Conductive Film | Barrier Film |
|---|---|---|
| SiO Film | Cu Film | TaN Film |
| SiN Film | Co Film | TiN Film |
| SiOC Film | Ru Film | |
| SiON Film | W Film | |
| SiOCN Film | | |
| SiCN Film | | |

A combination of the insulating film 11, the conductive film 12, and the barrier film 13 is not particularly limited.

Step S102 in FIG. 1 includes cleaning the substrate surface 1a as illustrated in FIG. 2B. A contaminant 22 (see FIG. 2A) present on the substrate surface 1a can be removed. The contaminant 22 includes, for example, at least one of a metal oxide and an organic material. The metal oxide is, for example, an oxide formed by a reaction between the conductive film 12 and the atmosphere and is a so-called natural oxide film. The organic material is, for example, a deposit containing carbon and adheres to the substrate 1 during a processing process.

For example, step S102 includes supplying a cleaning gas to the substrate surface 1a. The cleaning gas may be converted into plasma in order to improve the removal efficiency of the contaminant 22. The cleaning gas includes, for example, a reducing gas such as H₂ gas. The reducing gas removes the contaminant 22. Step S102 is a dry process but may also be a wet process.

An example of processing conditions for step S102 is as follows.
Flow rate of H₂ gas: 200 sccm to 3,000 sccm
Power supply frequency for plasma generation: 400 kHz to 40 MHz
Power for plasma generation: 50 W to 1,000 W
Processing time: 1 second to 60 seconds
Processing temperature: 50 degrees C. to 300 degrees C.
Processing pressure: 10 Pa to 7,000 Pa

Step S103 in FIG. 1 includes forming an oxide film 32 by oxidizing the surface of the conductive film 12 as illustrated in FIG. 2C. For example, step S103 includes forming the oxide film 32 by supplying an oxygen-containing gas to the substrate surface 1a. The oxygen-containing gas includes at least one selected from among O₂ gas, O₃ gas, H₂O gas, NO gas, NO₂ gas, and N₂O gas. Step S103 is a dry process but may be a wet process.

Because the contaminant 22 has been removed before step S103, the oxide film 32 having a desired film thickness and desired film quality is obtained by step S103. The film quality includes the surface state of a film. Unlike a natural oxide film, the film thickness and film quality of the oxide film 32 can be controlled according to a raw material gas and film formation conditions. By forming the oxide film 32 having a desired film thickness and desired film quality, a dense self-assembled monolayer (SAM) can be formed on the surface of the conductive film 12 in step S104 described later.

An example of processing conditions for step S103 is as follows.
Flow rate of O₂ gas: 100 sccm to 2,000 sccm
Processing time: 10 seconds to 300 seconds
Processing temperature: 100 degrees C. to 250 degrees C.
Processing pressure: 200 Pa to 1,200 Pa

Step S104 in FIG. 1 includes selectively forming a SAM 17 on the surface of the conductive film 12 with respect to the surface of the insulating film 11 using an organic compound not containing fluorine, as illustrated in FIG. 2D. The SAM 17 is formed by supplying gas of the organic compound into a processing container that accommodates the substrate 1. The organic compound is a precursor of the SAM 17.

The use of the organic compound not containing fluorine as the precursor of the SAM 17 contributes to environmental conservation. Compared with an organic compound that contains fluorine, the organic compound not containing fluorine hardly remains in the processing container accommodating the substrate 1, so that the stability (reproducibility) of the processing quality of the substrate 1 can be raised.

The organic compound includes, for example, a first functional group, and a second functional group provided at one end of the first functional group. The first functional group is, for example, a hydrocarbon group. The first functional group is desirably linear. The first functional group is desirably an alkyl group. The first functional group may have an unsaturated bond such as a double bond. The second functional group is chemically adsorbed to the surface of the conductive film 12.

The organic compound as the precursor of the SAM 17 is not particularly limited but may be, for example, a thiol-based compound. The thiol-based compound is represented by a general formula “R-SH”. R is, for example, a hydrocarbon group and corresponds to the first functional group. The SH group corresponds to the second functional group. A specific example of the thiol-based compound is CH₃(CH₂)ₓCH₂SH (where X is an integer of 1 to 16).

The thiol-based compound is more likely to be chemically adsorbed to the surface of the conductive film 12 than to the surface of the insulating film 11. Therefore, the SAM 17 is selectively formed on the surface of the conductive film 12 with respect to the surface of the insulating film 11. The SAM 17 is not formed on the surface of the insulating film 11 and is hardly formed on the surface of the barrier film 13.

When the oxide film 32 is formed before the SAM 17 is formed, the density of the SAM 17 can be improved compared to the case in which the oxide film 32 is not formed, and the blocking performance of the SAM 17 can be improved in steps S105 and S109 described later. Since the thiol-based compound is chemically adsorbed to the oxide film 32 while reducing the oxide film 32, the oxide film 32 does not necessarily have to remain after step S104 (see FIGS. 2D, 9D, and 12D).

The precursor of the SAM 17 is not limited to the thiol-based compound. For example, the precursor of the SAM 17 may be an organic silane-based compound, a phosphonic acid-based compound, or an isocyanate-based compound. The organic silane-based compound is represented by a general formula “R—Si(OCH₃)₃” or “R—SiCl₃”. The phosphonic acid-based compound is represented by a general formula “R—P(═O)(OH)₂”. The isocyanate-based compound is represented by a general formula “R—N═C═O”. In these general formulas, R is, for example, a hydrocarbon group.

An example of processing conditions for step S104 is as follows.
Flow rate of gas of organic compound: 50 sccm to 500 sccm
Processing time: 10 seconds to 1,800 seconds
Processing temperature: 100 degrees C. to 350 degrees C.
Processing pressure: 100 Pa to 14,000 Pa

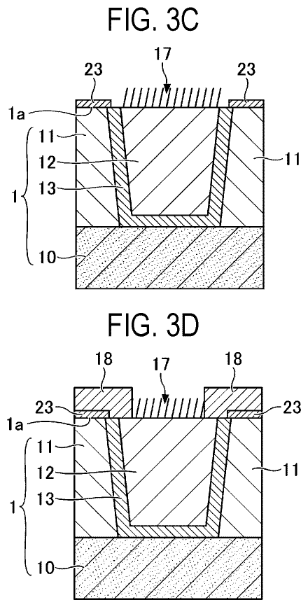

Step S105 in FIG. 1 includes forming a protective film 23 on the surface of the insulating film 11 while inhibiting the protective film 23 from being formed on the surface of the conductive film 12 using the SAM 17, as illustrated in FIG. 3A. The protective film 23 is, for example, an insulating film. The protective film 23 is formed not only on the surface of the insulating film 11, but also on the surface of the barrier film 13.

The protective film 23 is fluorinated instead of the insulating film 11 in step S106 described later, thereby preventing the insulating film 11 from being fluorinated. The protective film 23 may have a film thickness sufficient to prevent fluorination of the insulating film 11. The thickness is, for example, 0.1 nm to 2 nm.

The protective film 23 is not particularly limited but may be, for example, an AlO film, a SiO film, a SiN film, a ZrO film, or a HfO film. Here, the AlO film means a film containing aluminum (Al) and oxygen (O). The atomic ratio of Al to O in the AlO film is usually 2:3 but is not limited to 2:3. Similarly, each of the SiO film, SiN film, ZrO film, and HfO film also means a film containing corresponding elements and is not limited to a stoichiometric ratio.

The protective film 23 is formed, for example, by an atomic layer deposition (ALD) method. When the protective film 23 is formed by the ALD method, a precursor gas of the protective film 23 and a reaction gas are alternately supplied to the substrate surface 1a. The precursor gas of the protective film 23 contains, for example, a metal element or a metalloid element.

The reaction gas forms the protective film 23 by reacting with the precursor gas of the protective film 23. The reaction gas is, for example, an oxidizing gas or a nitriding gas. The oxidizing gas forms an oxide film of a metal element or a metalloid element contained in the precursor gas. The nitriding gas forms a nitride film of the metal element or the metalloid element contained in the precursor gas.

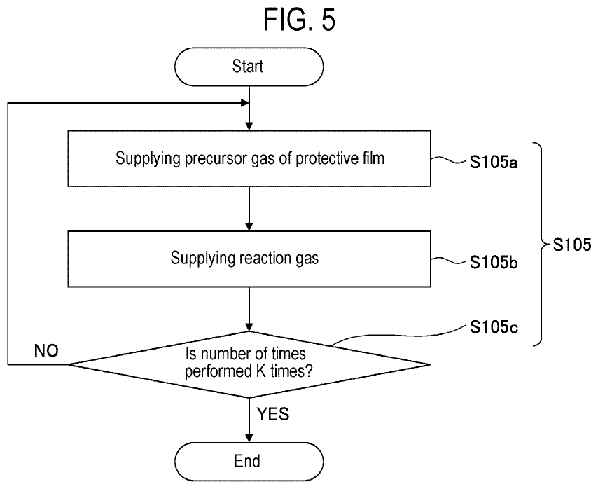

A method of forming the protective film 23 includes, for example, steps S105a to S105c illustrated in FIG. 5. The order of steps S105a and S105b may be reversed. In addition, between steps S105a and S105b, there may be a step of discharging various gases remaining in the processing container by supplying an inert gas such as argon gas into the processing container.

Step S105a includes supplying the precursor gas of the protective film 23 to the substrate surface 1a. Since the SAM 17 has been formed on the surface of the conductive film 12, the precursor gas is selectively adsorbed to the surface of the insulating film 11. An example of processing conditions for step S105a is shown below. In the processing conditions below, trimethylaluminum (TMA) gas is a precursor gas of an AlO film.
Flow rate of TMA gas: 1 sccm to 300 sccm (desirably 50 sccm)
Processing time: 0.1 seconds to 2 seconds
Processing temperature: 100 degrees C. to 250 degrees C.
Processing pressure: 133 Pa to 1,200 Pa

Step S105b includes supplying a reaction gas to the substrate surface 1a. The reaction gas forms the protective film 23 by reacting with the precursor gas of the protective film 23. An example of processing conditions for step S105b is shown below. In the processing conditions below, H₂O gas forms the AlO film by reacting with the TMA gas.
Flow rate of H₂O gas: 10 sccm to 200 sccm
Processing time: 0.1 seconds to 2 seconds
Processing temperature: 100 degrees C. to 250 degrees C.
Processing pressure: 133 Pa to 1,200 Pa

Step S105c includes checking whether steps S105a and S105b have been performed a set number of times (K times). The set number of times (K times) is determined according to a target film thickness of the protective film 23 and is, for example, 1 to 20 times. The target film thickness of the protective film 23 is, for example, 0.1 nm to 2 nm.

If the number of times performed has not reached the set number (K times) (“NO” in step S105c), the thickness of the protective film 23 has not reached the target thickness, so steps S105a and S105b are performed again. On the other hand, if the number of times performed has reached the set number (K times) (“YES” in step S105c), the thickness of the protective film 23 has reached the target thickness, so the processing of FIG. 5 is ended.

Step S106 in FIG. 1 includes fluorinating the SAM 17. At least a portion of hydrogen atoms contained in the SAM 17 are replaced with fluorine atoms. Thereby, the water repellency of the SAM 17 and the coverage of the SAM 17 are improved, and thus, the blocking performance of the SAM 17 is improved. The coverage of the SAM 17 is improved because the fluorine atoms have a larger atomic radius than the hydrogen atoms.

Step S106 also includes fluorinating the protective film 23, as illustrated in FIG. 3B. In FIG. 3B, a fluorinated portion 23a of the protective film 23 is represented by a dot pattern. The protective film 23 is fluorinated instead of the insulating film 11, thereby preventing fluorination of the insulating film 11. At least a portion of the protective film 23 may be fluorinated or the entirety of the protective film 23 may be fluorinated.

Step S106 includes, for example, supplying a fluorine-containing gas to the substrate surface 1a. The fluorine-containing gas is not particularly limited as long as the fluorine-containing gas contains fluorine but includes, for example, at least one selected from among HF gas, F₂ gas, and ClF₃ gas.

An example of processing conditions for step S106 is shown below.

Flow rate of fluorine-containing gas: 50 sccm to 500 sccm

Processing time: 1 second to 120 seconds

Processing temperature: 100 degrees C. to 400 degrees C.

Processing pressure: 1.333 Pa to 1,200 Pa

Step S107 of FIG. 1 includes etching the fluorinated portion 23a of the protective film 23 as illustrated in FIG. 3C. The fluorinated portion 23a of the protective film 23 can be removed.

Step S107 includes, for example, supplying an etching gas to the substrate surface 1a. The etching gas changes the fluorinated portion 23a of the protective film 23 into a volatile compound by a ligand exchange reaction. Thereby, the fluorinated portion 23a of the protective film 23 is etched.

The etching gas includes, for example, at least one selected from among trimethylaluminum (TMA) gas, dimethylacetamide (DMAC) gas, tin (II) acetylacetonate gas, Cl₂ gas, BCl₃ gas, and TiCl₄ gas. These gases change the fluorinated portion 23a of the protective film 23 into the volatile compound by the ligand exchange reaction.

For example, if the protective film 23 is an AlO film, at least a portion of the AlO film is an AlF film by fluorination. If the TMA (Al(CH₃)₃) gas is used as the etching gas, AlF(CH₃) 2 gas is generated and the AlF film is removed, by a ligand exchange reaction between the TMA gas and the AlF film.

An example of processing conditions for step S107 is shown below.
Flow rate of etching gas: 10 sccm to 500 sccm
Processing time: 1 second to 30 seconds
Processing temperature: 100 degrees C. to 400 degrees C.
Processing pressure: 10 Pa to 1,500 Pa

Step S108 in FIG. 1 includes checking whether step S107 (etching of the fluorinated portion of the protective film) has been performed a set number of times (J times) after step S106 (fluorination of the SAM and the protective film) is performed once, or whether step S106 and step S107 have been alternately performed a set number of times (J times).

If the number of times performed has not reached the set number of times (J times) (“NO” in step S108), the removal of the protective film 23 is insufficient, so step S107 is performed again, or step S106 and step S107 are performed again. On the other hand, if the number of times performed has reached the set number of times (J times) (“YES” in step S108), the removal of the protective film 23 is sufficient, so processing of step S109 and steps after S109 are performed.

J is an integer equal to or greater than 1 but is desirably an integer equal to or greater than 2. When J is an integer equal to or greater than 2, step S106 (fluorination of the SAM and the protective film) is performed once and then step S107 (etching of the fluorinated portion of the protective film) is repeatedly performed multiple times, or steps S106 and S107 are repeatedly performed alternately multiple times.

If step S106 is performed once and then step S107 is repeatedly performed multiple times, the fluorinated portion 23a of the protective film 23 can be easily removed. In addition, if step S106 and step S107 are repeatedly performed alternately multiple times, it is possible to remove the entire protective film 23, although not illustrated.

Step S109 in FIG. 1 includes forming a target film 18 on the surface of the protective film 23 while inhibiting the target film 18 from being formed on the surface of the conductive film 12 using the SAM 17, as illustrated in FIG. 3D. The target film 18 and the protective film 23 may be made of a same material or different materials. As described above, the entire protective film 23 may be removed, and in this case, the target film 18 is formed on the surface of the insulating film 11.

The target film 18 is, for example, an insulating film, and is deposited on the insulating film 11 via the protective film 23 or is deposited directly on the insulating film 11. The target film 18 is not particularly limited but may be, for example, an AlO film, a SiO film, a SiN film, a ZrO film, or a HfO film. Here, the AlO film means a film containing aluminum (Al) and oxygen (O). The atomic ratio of Al to O in the AlO film is usually 2:3 but is not limited to 2:3. Similarly, each of the SiO film, the SiN film, the ZrO film, and the HfO film means a film containing corresponding elements and is not limited to a stoichiometric ratio.

The target film 18 is formed, for example, by the ALD method. When the target film 18 is formed by the ALD method, a precursor gas of the target film 18 and a reaction gas are alternately supplied to the substrate surface 1a. The precursor gas of the target film 18 contains, for example, a metal element or a metalloid element.

The reaction gas forms the target film 18 by reacting with the precursor gas of the target film 18. The reaction gas is, for example, an oxidizing gas or a nitriding gas. The oxidizing gas forms an oxide film of the metal element or the metalloid element contained in the precursor gas. The nitriding gas forms a nitride film of the metal element or the metalloid element contained in the precursor gas.

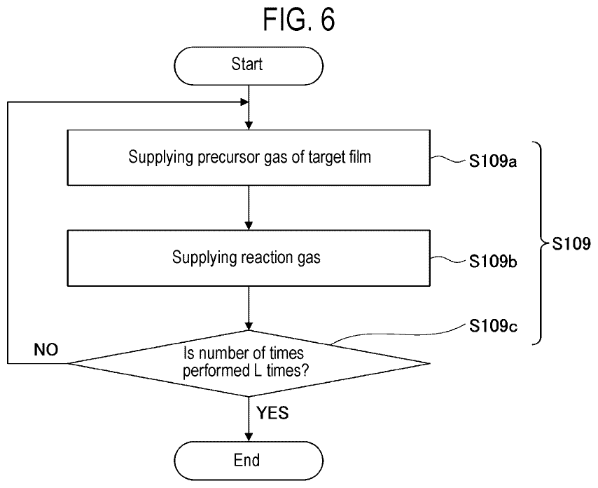

A method of forming the target film 18 includes, for example, steps S109a to S109c illustrated in FIG. 6. The order of steps S109a and S109b may be reversed. In addition, between steps S109a and S109b, there may be a step of discharging various gases remaining in the processing container by supplying an inert gas such as argon gas into the processing container.

Step S109a includes supplying the precursor gas of the target film 18 to the substrate surface 1a. Since the SAM 17 has been formed on the surface of the conductive film 12, the precursor gas is selectively adsorbed to the surface of the insulating film 11. An example of processing conditions for step S109 is shown below. In the processing conditions below, TMA gas is a precursor gas of an AlO film.
Flow rate of TMA gas: 1 sccm to 300 sccm (desirably 50 sccm)
Processing time: 0.1 seconds to 2 seconds
Processing temperature: 100 degrees C. to 250 degrees C.
Processing pressure: 133 Pa to 1,200 Pa

Step S109b includes supplying a reaction gas to the substrate surface 1a. The reaction gas forms the target film 18 by reacting with the precursor gas of the target film 18. An example of processing conditions for step S106 is shown below. In the processing conditions below, the H₂O gas forms the AlO film by reacting with the TMA gas.
Flow rate of H₂O gas: 10 sccm to 200 sccm
Processing time: 0.1 seconds to 2 seconds
Processing temperature: 100 degrees C. to 250 degrees C.
Processing pressure: 133 Pa to 1,200 Pa

Step S109c includes checking whether steps S109a and S109b have been performed a set number of times (L times). The set number of times (L times) is determined according to a target film thickness of the target film 18 and is, for example, 20 to 80 times. The target film thickness of the target film 18 is thicker than the target film thickness of the protective film 23. The target film thickness of the target film 18 is, for example, 2 nm to 10 nm.

If the number of times performed has not reached the set number of times (L times) (“NO” in step S109c), the film thickness of the target film 18 has not reached the target film thickness, so steps S109a and S109b are performed again. On the other hand, if the number of times performed has reached the set number of times (L times) (“YES” in step S109c), the film thickness of the target film 18 has reached the target film thickness, so the processing of FIG. 6 is ended.

According to the embodiment, the target film 18 can be formed in a state in which the blocking performance of the SAM 17 is improved by fluorinating the SAM 17 in advance. In addition, the deterioration of the insulating film 11 can be suppressed by protecting the insulating film 11 with the protective film 23 when fluorinating the SAM 17. The protective film 23 is fluorinated instead of the insulating film 11. The fluorinated portion 23a of the protective film 23 is removed by etching before the target film 18 is formed.

However, as illustrated in FIG. 3D, while the SAM 17 inhibits the target film 18 from being formed, the blocking performance of the SAM 17 is not perfect. Therefore, the target film 18 may protrude from the surface of the insulating film 11 and be formed even on the surface of the conductive film 12. If the target film 18 exists on the conductive film 12, the wiring resistance of the substrate 1 increases. Therefore, step S110 described below may be performed.

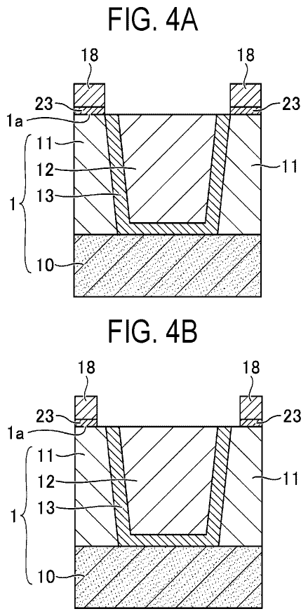

Step S110 of FIG. 1 includes decomposing the fluorinated SAM 17 and etching a side portion of the target film 18 adjacent to the SAM 17, as illustrated in FIG. 4A or FIG. 4B. Since the side portion of the target film 18 can be removed from above the conductive film 12, the wiring resistance of the substrate 1 can be reduced.

The side portion of the target film 18 is removed from above the conductive film 12, and a center portion of the target film 18 is left on the insulating film 11. As illustrated in FIG. 4A, the surface of the insulating film 11 may not be exposed, or as illustrated in FIG. 4B, a part of the surface of the insulating film 11 may be exposed. After step S110, only the target film 18 needs to remain on the insulating film 11.

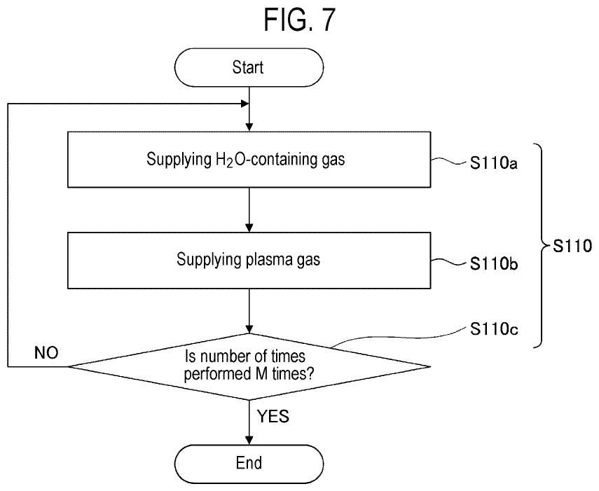

Step S110 includes, for example, steps S110a to S110c illustrated in FIG. 7. The order of steps S110a and S110b may be reversed. Step S110b (supply of plasma gas) may be omitted, and only step S110a (supply of H₂O-containing gas) may be performed.

Step S110a includes supplying H₂O-containing gas to the substrate surface 1a. The H₂O-containing gas may contain only H₂O gas or may contain H₂O gas and a carrier gas. The H₂O-containing gas may contain an organic acid gas such as carboxylic acid in addition to the H₂O gas.

The SAM 17 is fluorinated in advance and contains fluorine. Therefore, hydrofluoric acid is generated by a reaction between the H₂O gas and the SAM 17. The generated hydrofluoric acid reacts with the side portion of the target film 18 to convert the side portion of the target film 18 into a volatile compound. Thereby, the side portion of the target film 18 is etched.

Since the hydrofluoric acid is generated by the reaction between H₂O gas and the SAM 17, the hydrofluoric acid is generated only in the vicinity of the SAM 17. Thereby, while the side portion of the target film 18 is etched, the center portion of the target film 18 is not etched. Therefore, the target film 18 can be left on the insulating film 11.

An example of processing conditions for step S110a is shown below.
Flow rate of H₂O gas: 50 sccm to 200 sccm
Processing time: 1 second to 30 seconds
Processing temperature: 100 degrees C. to 250 degrees C.
Processing pressure: 133 Pa to 1,200 Pa

In step S110b, a plasma gas is supplied to the substrate surface 1a. The plasma gas is obtained by converting, for example, at least one selected from among H₂ gas, Ar gas, N₂ gas, and NH₃ gas into plasma. The plasma gas promotes the decomposition of the SAM 17 to promote the generation of the hydrofluoric acid. Since the hydrofluoric acid is acidic, it is desirable that the plasma gas be obtained by converting a reducing gas or an inert gas into plasma so as not to neutralize the hydrofluoric acid.

An example of processing conditions for step S110b is shown below.
Flow rate of H₂ gas: 200 sccm to 3,000 sccm
Flow rate of Ar gas: 100 sccm to 6,000 sccm
Ratio of H₂ gas to mixed gas of H₂ gas and Ar gas: 20 vol % to 90 vol %
Power supply frequency for plasma generation: 400 kHz to 40 MHz
Power for plasma generation: 100 W to 600 W
Processing time: 10 seconds to 30 seconds
Processing temperature: 100 degrees C. to 250 degrees C.
Processing pressure: 133 Pa to 1,200 Pa

Step S110c includes checking whether steps S110a and S110b have been performed a set number of times (M times). If the number of times performed has not reached the set number of times (M times) (“NO” in step S110c), the etching of the target film 18 is insufficient, so steps S110a and S110b are performed again. On the other hand, if the number of times performed has reached the set number of times (M times) (“YES” in step S110c), the etching of the target film 18 is sufficient, so the processing of FIG. 7 is ended.

The set number of times (M times) of step S110c may be one time but is desirably multiple times. By dividing the supply of the plasma gas into multiple times, the decomposition of the SAM 17 can be gradually performed, the hydrofluoric acid can be generated over a long period of time, and the target film 18 can be etched over a long period of time. The set number of times (M times) in step S110c is, for example, 5 to 50.

In FIG. 7, although the H₂O-containing gas and the plasma gas are sequentially supplied and are not simultaneously supplied, the H₂O-containing gas and the plasma gas may be simultaneously supplied. In any case, since the SAM 17 can be decomposed by the supply of the plasma gas, the generation of the hydrofluoric acid can be promoted. However, if the H₂O-containing gas and the plasma gas are sequentially supplied, the H₂O-containing gas can be prevented from being converted into plasma, and the generation of oxygen radicals and hydroxyl radicals can be prevented from occurring, so that oxidation of the substrate surface 1a can be prevented.

Step S110 is not limited to that illustrated in FIG. 7. For example, step S110 may include supplying a hydrogen-containing gas converted into plasma to the substrate surface 1a. The hydrogen-containing gas may be any gas containing hydrogen but includes, for example, at least one selected from among H₂ gas, H₂O gas, NH₃ gas, N₂H₄ gas, and a hydrocarbon gas, but is not particularly limited thereto. The hydrocarbon gas is, for example, CH₄ gas.

The SAM 17 is fluorinated in advance and contains fluorine and carbon. The hydrogen-containing gas converted into plasma excites the SAM 17, so that active species containing fluorine and carbon are generated. The generated active species reacts with the side portion of the target film 18 and changes the side portion of the target film 18 into a volatile compound. Thereby, the side portion of the target film 18 is etched.

Since the active species containing fluorine and carbon are generated by a reaction between the hydrogen-containing gas converted into plasma and the SAM 17, the active species are generated only in the vicinity of the SAM 17. Therefore, the side portion of the target film 18 is etched, whereas the center portion of the target film 18 is not etched. Accordingly, the target film 18 can be left on the insulating film 11.

An example of processing conditions for step S110 when using the hydrogen-containing gas converted into plasma is shown below.
Flow rate of H₂ gas: 200 sccm to 3,000 sccm
Power supply frequency for plasma generation: 400 kHz to 40 MHz
Power for plasma generation: 50 W to 1,000 W
Processing time: 1 second to 60 seconds
Processing temperature: 50 degrees C. to 300 degrees C.
Processing pressure: 10 Pa to 7,000 Pa

Step S110 may include decomposing the SAM 17 by supplying the plasma gas to the substrate surface 1a, fluorinating the side portion of the target film 18 using the active species contained in the decomposed SAM 17, and etching the fluorinated side portion of the target film 18 using an etching gas. The fluorination of the side portion of the target film 18 is performed in the same manner as in step S106. The etching of the fluorinated side portion of the target film 18 is performed in the same manner as in step S107. The fluorination and etching may be repeatedly performed.

If the thickness of the target film 18 remaining after step S110 has reached a second target thickness, current processing is terminated. Meanwhile, if the thickness of the target film 18 remaining after step S110 has not reached the second target thickness, processing illustrated in FIG. 8 is performed. The second target thickness may be the same as a target thickness corresponding to the set number of times (L times) in FIG. 6 or may be greater than the target thickness.

Since the SAM 17 is decomposed in step S110 of the first time illustrated in FIG. 1, steps S103 and S104 are performed again to re-form the SAM 17 as illustrated in FIG. 8. Processing performed thereafter differs depending on whether a part of the surface of the insulating film 11 is exposed by step S110 of the first time.

If a part of the surface of the insulating film 11 is exposed in step S110 of the first time as illustrated in FIG. 4B (“YES” in step S111), step S105 is performed again in order to protect the insulating film 11, and the protective film 23 is re-formed. Next, steps S106 to S110 are performed again.

On the other hand, if the surface of the insulating film 11 is not exposed in the first step S110 as illustrated in FIG. 4A and remains covered by the target film 18 (“NO” in step S111), protection of the insulating film 11 is not necessary. Therefore, step S105 (forming the protective film) is not performed again, and steps S106 to S110 are performed again.

Thereafter, if the number of times of performing steps S109 and S110 has not reached a set number (N times) (“NO” in step S112), the thickness of the target film 18 has not reached the second target thickness, so processing of step S103 and subsequent steps in FIG. 8 is performed again.

On the other hand, if the number of times of performing steps S109 and S110 has reached the set number (N times) (“YES” in step S112), the thickness of the target film 18 has reached the second target thickness, so current processing is ended.

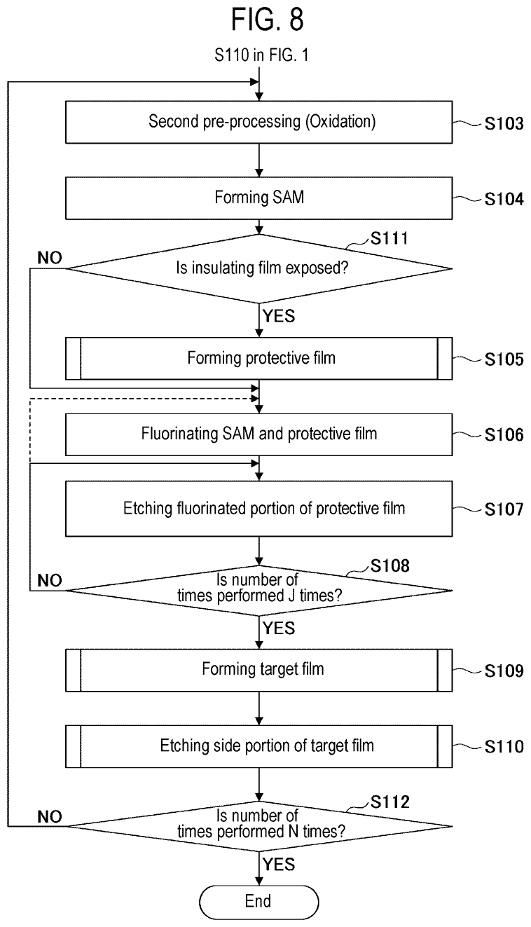

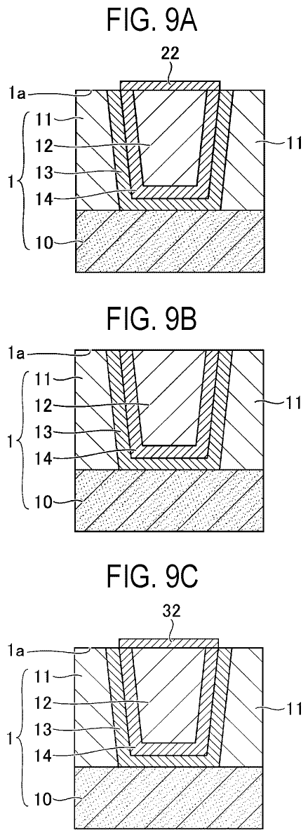

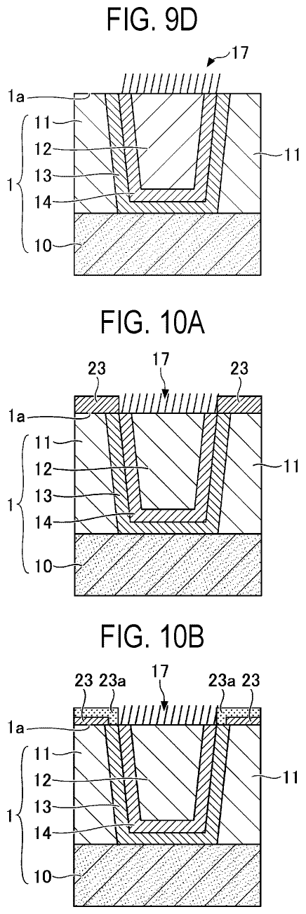

Next, the case in which the substrate 1 according to a first modified example is processed by the method of FIG. 1 will be described with reference to FIGS. 9A to 11B. The substrate 1 illustrated in FIG. 9A may be processed by the method of FIG. 1 and then also be processed by the method of FIG. 8. Hereinafter, differences will mainly be described.

As illustrated in FIG. 9A, the substrate 1 may have a liner film 14, in addition to the insulating film 11, the conductive film 12, and the barrier film 13, on the substrate surface 1a. The liner film 14 is formed between the conductive film 12 and the barrier film 13. The liner film 14 is formed on the barrier film 13 and assists in the formation of the conductive film 12. The conductive film 12 is formed on the liner film 14. The liner film 14 is not particularly limited but is, for example, a Co film or a Ru film.

Table 2 summarizes a specific example of the insulating film 11, the conductive film 12, the barrier film 13, and the liner film 14.

TABLE 2

| Insulating Film | Conductive Film | Barrier Film | Liner Film |
|---|---|---|---|
| SiO Film | Cu Film | TaN Film | Co Film |
| SiN Film | | TiN Film | Ru Film |
| SiOC Film | | | |
| SiON Film | | | |
| SiOCN Film | | | |
| SiCN Film | | | |

A combination of the insulating film 11, the conductive film 12, the barrier film 13, and the liner film 14 is not particularly limited.

Step S102 according to the modified example includes removing the contaminant 22 (see FIG. 9A) as illustrated in FIG. 9B. The contaminant 22 is present, for example, on the surface of the conductive film 12 and the surface of the liner film 14. The surface of the conductive film 12 and the surface of the liner film 14 are exposed by step S102.

Step S103 according to the modified example includes forming the oxide film 32 by oxidizing the surface of the conductive film 12 and the surface of the liner film 14, as illustrated in FIG. 9C. Thereby, the dense SAM 17 can be formed on the surface of the conductive film 12 and the surface of the liner film 14 in step S104 described below.

Step S104 according to the modified example includes selectively forming the SAM 17 on the surface of the conductive film 12 and the surface of the liner film 14 with respect to the surface of the insulating film 11, as illustrated in FIG. 9D. The SAM 17 is not formed on the surface of the insulating film 11 and is hardly formed on the surface of the barrier film 13.

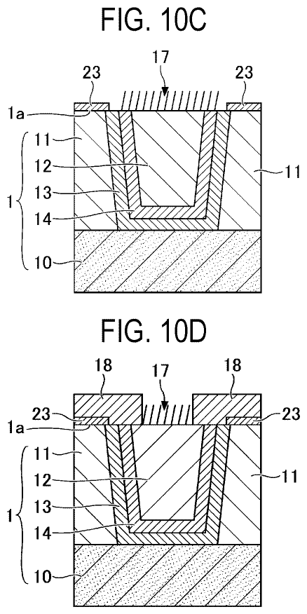

Step S105 according to the modified example includes forming the protective film 23 on the surface of the insulating film 11 while inhibiting the protective film 23 from being formed on the surface of the conductive film 12 and the surface of the liner film 14 using the SAM 17, as illustrated in FIG. 10A. The protective film 23 is formed not only on the surface of the insulating film 11, but also on the surface of the barrier film 13.

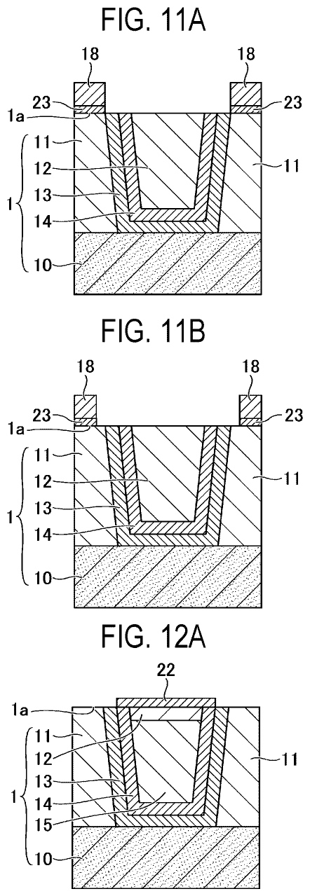

Steps S106 to S110 according to the modified example (see FIGS. 10B to 10D, 11A, and 11B) are performed in the same manner as steps S106 to S110 of the embodiment (see FIGS. 3B to 3D, 4A, and 4B).

Even in the modified example, the target film 18 can be formed in a state in which the blocking performance of the SAM 17 is improved by fluorinating the SAM 17 in advance, as in the embodiment. In addition, when the SAM 17 is fluorinated, the deterioration of the insulating film 11 can be suppressed by protecting the insulating film 11 by the protective film 23. The protective film 23 is fluorinated instead of the insulating film 11. The fluorinated portion 23a of the protective film 23 is removed by etching before the target film 18 is formed.

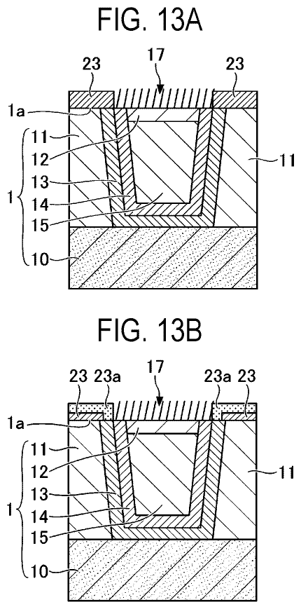

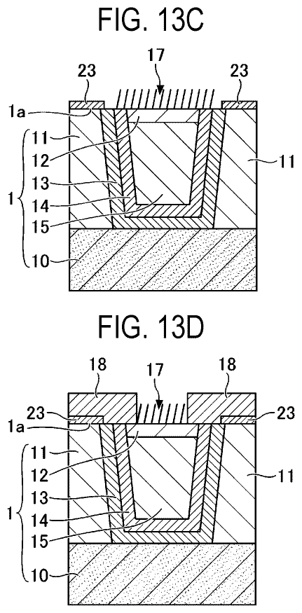

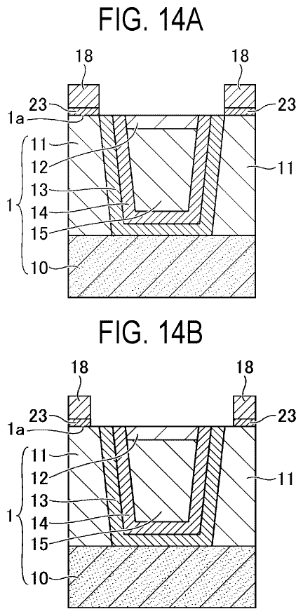

Next, the case in which the substrate 1 according to a second modified example is processed by the method of FIG. 1 will be described with reference to FIGS. 12A to 14B. The substrate 1 illustrated in FIG. 12A may be processed by the method of FIG. 1 and then also be processed by the method of FIG. 8. Hereinafter, differences will mainly be described.

As illustrated in FIG. 12A, the conductive film 12 of the substrate 1 may be a cap film. That is, as illustrated in FIG. 12A, the second conductive film 15 may be filled in the recess of the insulating film 11, and the conductive film 12 may cover the second conductive film 15. The second conductive film 15 is formed of a metal different from that of the conductive film 12.

Table 3 summarizes a specific example of the conductive film (cap film) 12, the barrier film 13, the liner film 14, and the second conductive film 15.

TABLE 3

| | | | | Second |
|---|---|---|---|---|
| Insulating | Conductive | | | Conductive |
| Film | Film (Cap Film) | Barrier Film | Liner Film | Film |
| SiO Film | Co Film | TaN Film | Co Film | Cu Film |
| SiN Film | Ru Film | TiN Film | Ru Film | |
| SiOC Film | | | | |
| SiON Film | | | | |
| SiOCN Film | | | | |
| SiCN Film | | | | |

Further, a combination of the insulating film 11, the conductive film 12, the barrier film 13, the liner film 14, and the second conductive film 15 is not particularly limited.

Steps S102 to S110 according to the second modified example (see FIGS. 12B to 12D, 13A to 13D, 14A, and 14B) are performed in the same manner as steps S102 to S110 according to the first modified example (see FIGS. 9B to 9D, 10A to 10D, 11A, and 11B).

Further, in the embodiment, the first modified example, and the second modified example, the insulating film 11 corresponds to a first film and the conductive film 12 corresponds to a second film, but a combination of the first film and the second film is not particularly limited.

Table 4 shows candidates of a combination of the first film, the second film, and the target film 18 when the precursor of the SAM 17 is a thiol-based compound.

TABLE 4

| SAM | First Film | Second Film | Target Film |
|---|---|---|---|
| Thiol-based | SiN Film | Cu Film | AlO Film |
| | SiO Film | TaN Film | SiO Film |
| | SiOC Film | TiN Film | SiN Film |
| | SiON Film | Co Film | ZrO Film |
| | SiOCN Film | Ru Film | HfO Film |
| | SiCN Film | Au Film | |
| | Spin-On Carbon Film | | |

The candidates listed in Table 4 can be used in any combination. It is desirable that the first film be an insulating film, the second film be a conductive film, and the target film 18 formed on the surface of the first film be an insulating film.

Table 5 shows candidates of a combination of the first film, the second film, and the target film 18 when the precursor of the SAM 17 is a phosphonic acid-based compound.

TABLE 5

| SAM | First Film | Second Film | Target Film |
|---|---|---|---|
| Phosphonic | SiN Film | Cu Film | AlO Film |
| acid-based | SiO Film | TaN Film | SiO Film |
| | SiOC Film | TiN Film | SiN Film |
| | SiON Film | Co Film | ZrO Film |
| | SiOCN Film | | HfO Film |
| | SiCN Film | | |
| | Spin-On Carbon Film | | |

The candidates listed in Table 5 are used in any combination. It is desirable that the first film be an insulating film, the second film be a conductive film, and the target film 18 formed on the surface of the first film be an insulating film.

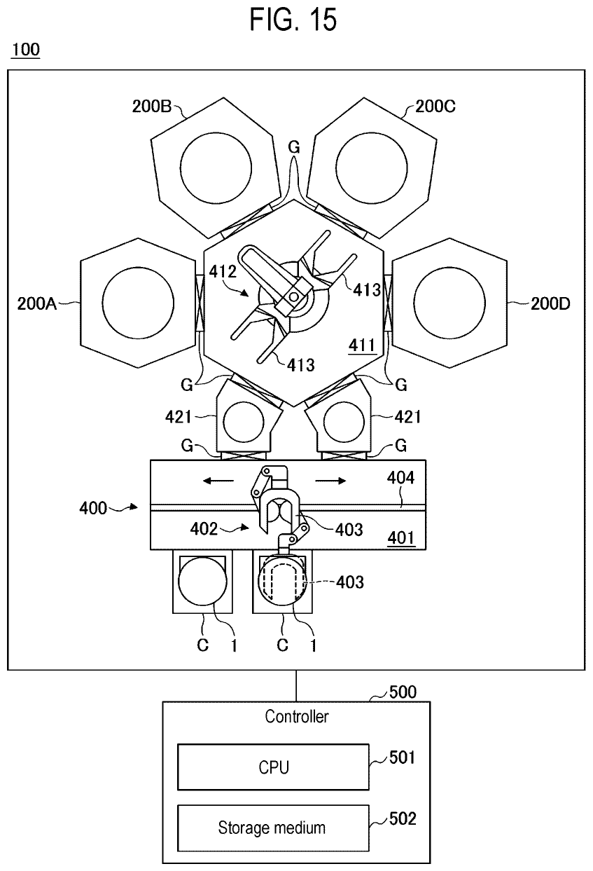

Next, a film forming apparatus 100 for performing the above film forming method will be described with reference to FIG. 15. As illustrated in FIG. 15, the film forming apparatus 100 has a first processor 200A, a second processor 200B, a third processor 200C, a fourth processor 200D, a fifth processor (not illustrated), and a controller 500. The first processor 200A performs steps S102 and S103 in FIG. 1. The second processor 200B performs step S104 in FIG. 1. The third processor 200C performs steps S105 and S109 in FIG. 1. The fourth processor 200D performs steps S106 and S107 in FIG. 1. The fifth processor performs step S110 in FIG. 1. The first processor 200A, the second processor 200B, the third processor 200C, the fourth processor 200D, and the fifth processor have the same structure. Therefore, it is possible to perform all of steps S102 to S107, S109, and S110 only in the first processor 200A. The first processor 200A, the second processor 200B, the third processor 200C, the fourth processor 200D, and the fifth processor may have different structures. A transfer portion 400 transfers the substrate 1 to the first processor 200A, the second processor 200B, the third processor 200C, the fourth processor 200D, and the fifth processor. The controller 500 controls the first processor 200A, the second processor 200B, the third processor 200C, the fourth processor 200D, the fifth processor, and the transfer portion 400.

The transfer portion 400 has a first transfer chamber 401 and a first transfer mechanism 402. An internal atmosphere of the first transfer chamber 401 is an atmospheric atmosphere. The first transfer mechanism 402 is provided inside the first transport chamber 401. The first transfer mechanism 402 includes an arm 403 that holds the substrate 1 and travels along a rail 404. The rail 404 extends in an arrangement direction of a carrier C.

The transfer portion 400 also has a second transfer chamber 411 and a second transfer mechanism 412. An internal atmosphere of the second transport chamber 411 is a vacuum atmosphere. The second transfer mechanism 412 is provided inside the second transfer chamber 411. The second transfer mechanism 412 includes an arm 413 that holds the substrate 1. The arm 413 is arranged to be movable in a vertical direction and a horizontal direction and rotatable around a vertical axis. Each of the first processor 200A, the second processor 200B, the third processor 200C, the fourth processor 200D, and the fifth processor is connected to the second transfer chamber 411 via a different gate valve G.

Further, the transfer portion 400 has a load lock chamber 421 between the first transfer chamber 401 and the second transfer chamber 411. An internal atmosphere of the load lock chamber 421 is switched between a vacuum atmosphere and an atmospheric atmosphere by a pressure regulating mechanism which is not illustrated. Thereby, the inside of the second transfer chamber 411 can always be maintained in the vacuum atmosphere. In addition, gas can be suppressed from flowing into the second transfer chamber 411 from the first transfer chamber 401. Gate valves G are provided between the first transfer chamber 401 and the load lock chamber 421 and between the second transfer chamber 411 and the load lock chamber 421.

The controller 500 is, for example, a computer and has a central processing unit (CPU) 501 and a storage medium 502 such as a memory. The storage medium 502 stores a program for controlling various processes executed in the film forming apparatus 100. The controller 500 controls the operation of the film forming apparatus 100 by causing the CPU 501 to execute the program stored in the storage medium 502. The controller 500 controls the first processor 200A, the second processor 200B, the third processor 200C, the fourth processor 200D, the fifth processor, and the transfer portion 400 to perform the film forming method.

Next, the operation of the film forming apparatus 100 will be described. First, the first transfer mechanism 402 takes the substrate 1 out of the carrier C, transfers the taken-out substrate 1 to the load lock chamber 421, and then exits from the load lock chamber 421. The internal atmosphere of the load lock chamber 421 is then switched from the atmospheric atmosphere to the vacuum atmosphere. Thereafter, the second transfer mechanism 412 takes the substrate 1 out of the load lock chamber 421 and transfers the taken-out substrate 1 to the first processor 200A.

Next, the first processor 200A performs steps S102 and S103 in FIG. 1. Thereafter, the second transfer mechanism 412 takes the substrate 1 out of the first processor 200A and transfers the taken-out substrate 1 to the second processor 200B. During this time, an ambient atmosphere of the substrate 1 can be maintained in the vacuum atmosphere.

Next, the second processor 200B performs step S104 in FIG. 1. Thereafter, the second transfer mechanism 412 takes the substrate 1 out of the second processor 200B and transfers the taken-out substrate 1 to the third processor 200C. During this time, the ambient atmosphere of the substrate 1 can be maintained in the vacuum atmosphere, so that the deterioration of the blocking performance of the SAM 17 can be suppressed.

Next, the third processor 200C performs step S105 in FIG. 1. Thereafter, the second transfer mechanism 412 takes the substrate 1 out of the third processor 200C and transfers the taken-out substrate 1 to the fourth processor 200D. During this time, the ambient atmosphere of the substrate 1 can be maintained in the vacuum atmosphere, so that the deterioration of the blocking performance of the SAM 17 can be suppressed.

Next, the fourth processor 200D performs steps S106 and S107 in FIG. 1 a set number of times. Thereafter, the second transfer mechanism 412 takes the substrate 1 out of the fourth processor 200D and transfers the taken-out substrate 1 to the third processor 200C. During this time, the ambient atmosphere of the substrate 1 can be maintained in the vacuum atmosphere, so that the deterioration of the blocking performance of the SAM 17 can be suppressed.

Next, the third processor 200C performs step S109 in FIG. 1. Thereafter, the second transfer mechanism 412 takes the substrate 1 out of the third processor 200C and transfers the taken-out substrate 1 to the fifth processor. During this time, the ambient atmosphere of the substrate 1 can be maintained in the vacuum atmosphere.

Next, the fifth processor performs step S110 in FIG. 1. Thereafter, the second transfer mechanism 412 takes the substrate 1 out of the substrate 1, transfers the taken-out substrate 1 to the load lock chamber 421, and then exits from the load lock chamber 421. The internal atmosphere of the load lock chamber 421 is then switched from the vacuum atmosphere to the atmospheric atmosphere. Thereafter, the first transfer mechanism 402 takes the substrate 1 out of the load lock chamber 421 and accommodates the taken-out substrate 1 in the carrier C. Then, processing of the substrate 1 is ended.

The film forming apparatus 100 can also perform steps S103 to S112 illustrated in FIG. 8.

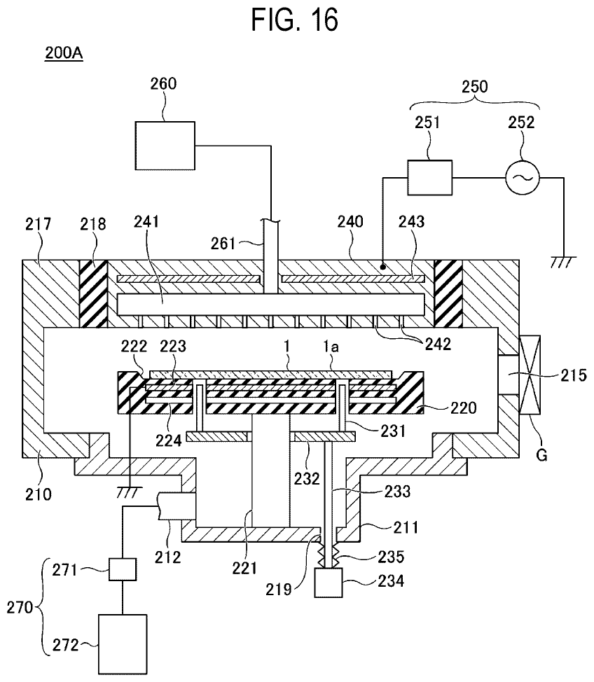

Next, the first processor 200A will be described with reference to FIG. 16. The second processor 200B, the third processor 200C, the fourth processor 200D, and the fifth processor are configured in the same manner as the first processor 200A, and therefore, illustration and description thereof will be omitted.

The first processor 200A includes a substantially cylindrical airtight processing container 210. An exhaust chamber 211 is provided at a center portion of a bottom wall of the processing container 210. The exhaust chamber 211 has, for example, a substantially cylindrical shape that protrudes downward. An exhaust pipe 212 is connected to the exhaust chamber 211, for example, on the side of the exhaust chamber 211.

An exhaust source 272 is connected to the exhaust pipe 212 via a pressure controller 271. The pressure controller 271 includes, for example, a pressure regulating valve such as a butterfly valve. The exhaust pipe 212 is configured to depressurize the interior of the processing container 210 by the exhaust source 272. The pressure controller 271 and the exhaust source 272 constitute a gas discharge mechanism 270 that discharges gas in the processing container 210.

A transfer port 215 is provided on the side of the processing container 210. The transfer port 215 is opened and closed by a gate valve G. The substrate 1 is loaded and unloaded between the inside of the processing container 210 and the second transfer chamber 411 (see FIG. 5) through the transfer port 215.

A stage 220, which is a holder for holding the substrate 1, is provided inside the processing container 210. The stage 220 holds the substrate 1 horizontally, with the substrate surface 1a facing upward. The stage 220 is formed in a substantially circular shape in a plan view and is supported by a support member 221. A substantially circular recess 222 is formed on the surface of the stage 220 to place the substrate 1 having a diameter of, for example, 300 mm. The recess 222 has an inner diameter slightly larger than the diameter of the substrate 1. The depth of the recess 222 is substantially the same as, for example, the thickness of the substrate 1. The stage 220 is made of, for example, a ceramic material such as aluminum nitride (AlN). The stage 220 may also be made of a metal material such as nickel (Ni). Instead of the recess 222, a guide ring that guides the substrate 1 may be provided at a peripheral edge of the surface of the stage 220.

In the stage 220, a grounded lower electrode 223, for example, is buried. A heating mechanism 224 is embedded below the lower electrode 223. The heating mechanism 224 heats the substrate 1 placed on the stage 220 to a set temperature by being fed with power from a power supply (not illustrated) based on a control signal from the controller 500 (see FIG. 15). When the entire stage 220 is made of a metal, the entire stage 220 functions as a lower electrode, so that the lower electrode 223 does not need to be buried in the stage 220. The stage 220 is provided with a plurality of (e.g., three) lifting pins 231 for supporting and raising and lowering the substrate 1 placed on the stage 220. The material of the lifting pins 231 may be, for example, ceramic such as alumina (Al₂O₃), or quartz. Lower ends of the lifting pins 231 are attached to a support plate 232. The support plate 232 is connected to a lifting mechanism 234 provided outside the processing container 210 via a lifting shaft 233.

The lifting mechanism 234 is installed, for example, below the exhaust chamber 211. A bellows 235 is provided between an opening 219 for the lifting shaft 233 formed in a lower surface of the exhaust chamber 211, and the lifting mechanism 234. The support plate 232 may be shaped to be raised and lowered without interfering with the support member 221 of the stage 220. The lifting pins 231 are configured to be capable of being elevated between an upper surface of the stage 220 and a lower surface of the stage 220 by the lifting mechanism 234.

A gas supply 240 is provided in a ceiling wall 217 of the processing container 210 via an insulating member 218. The gas supply 240 constitutes an upper electrode and faces the lower electrode 223. A radio-frequency power supply 252 is connected to the gas supply 240 via a matcher 251. By supplying a radio-frequency power of 400 kHz to 40 MHz from the radio-frequency power supply 252 to the upper electrode (gas supply 240), a radio-frequency electric field is generated between the upper electrode (gas supply 240) and the lower electrode 223 to generate capacitively coupled plasma. A plasma generator 250 that generates plasma includes the matcher 251 and the radio-frequency power supply 252. The plasma generator 250 may be a plasma generator that generates other plasma, such as inductively coupled plasma, without being limited to the capacitively coupled plasma. In a process in which plasma is not generated, the gas supply 240 does not need to constitute the upper electrode, and the lower electrode 223 is also unnecessary.

The gas supply 240 includes a hollow gas supply chamber 241. A plurality of holes 242 for dispersing and supplying a process gas into the processing container 210 is arranged, for example, uniformly, on a lower surface of the gas supply chamber 241. In the gas supply 240, a heating mechanism 243 is buried, for example, above the gas supply chamber 241. The heating mechanism 243 is heated to a set temperature by being fed with power from the power supply (not illustrated) based on the control signal from the controller 500.

A gas supply mechanism 260 is connected to the gas supply chamber 241 via a gas supply path 261. The gas supply mechanism 260 supplies gas used in at least one of steps S102 to S107, S109, or S110 in FIG. 1 to the gas supply chamber 241 via the gas supply path 261. Although not illustrated, the gas supply mechanism 260 includes an individual pipe, an on-off valve provided in the middle of the individual pipe, and a flow rate controller provided in the middle of the individual pipe, for each type of gas. When the individual pipe is opened by the on-off valve, gas is supplied from a supply source to the gas supply path 261. The amount of supply of the gas is controlled by the flow rate controller. On the other hand, when the individual pipe is closed by the on-off valve, the supply of the gas from the supply source to the gas supply path 261 is stopped.

While the embodiments of the film forming method and the film forming apparatus according to the present disclosure have been described, the present disclosure is not limited to the above embodiments. Various changes, modifications, substitutions, additions, deletions, and combinations are possible within the scope of the claims. These naturally fall within the technical scope of the present disclosure.

This application claims priority based on Japanese Patent Application No. 2022-049570 filed on Mar. 25, 2022, and the disclosure of Japanese Patent Application No. 2022-049570 is incorporated into this application in its entirety.

### EXPLANATION OF REFERENCE NUMERALS

1: substrate, 1a: substrate surface, 11: insulating film (first film), 12: conductive film (second film), 17: self-assembled monolayer (SAM), 18: target film

1. A film forming method, comprising:
(A) preparing a substrate having a first film and a second film made of a material different from a material of the first film in different regions of a surface of the substrate;
(B) selectively forming a self-assembled monolayer (SAM) on a surface of the second film with respect to a surface of the first film using an organic compound not containing fluorine;
(C) after (B), forming a protective film on the surface of the first film while inhibiting the protective film from being formed on the surface of the second film using the SAM;
(D) after (C), fluorinating the SAM and the protective film;
(E) after (D), etching a fluorinated portion of the protective film; and
(F) after (E), forming a target film on a surface of the protective film or the surface of the first film while inhibiting the target film from being formed on the surface of the second film using the fluorinated SAM.

2. The film forming method of claim 1, wherein the organic compound used in (B) includes a hydrocarbon group and a functional group provided at one end of the hydrocarbon group, and
wherein the functional group is chemically adsorbed to the surface of the second film.

3. The film forming method of claim 1, wherein a film thickness of the protective film formed on the surface of the first film in (C) is 2 nm or less.

4. The film forming method of claim 1, wherein (D) includes supplying a fluorine-containing gas to the surface of the substrate.

5. The film forming method of claim 4, wherein the fluorine-containing gas includes at least one selected from among HF gas, F₂ gas, and ClF₃ gas.

6. The film forming method of claim 1, wherein (E) includes supplying at least one selected from among trimethylaluminum (TMA) gas, dimethylacetamide (DMAC) gas, tin (II) acetylacetonate gas, Cl₂ gas, BCl₃ gas, and TiCl₄ gas to the surface of the substrate.

7. The film forming method of claim 1, wherein (E) is repeatedly performed multiple times after performing (D) once.

8. The film forming method of claim 1, further comprising
(G) after (F), decomposing the SAM and etching a side portion of the target film adjacent to the SAM.

9. The film forming method of claim 8, wherein (G) includes supplying an H₂O-containing gas to the surface of the substrate.

10. The film forming method of claim 8, wherein (G) includes supplying a hydrogen-containing gas converted into plasma to the surface of the substrate.

11. The film forming method of claim 8, wherein (G) includes supplying at least one selected from among trimethylaluminum (TMA) gas, dimethylacetamide (DMAC) gas, tin (II) acetylacetonate gas, Cl₂ gas, BCl₃ gas, and TiCl₄ gas to the surface of the substrate.

12. The film forming method of claim 1, wherein one of the first film and the second film is an insulating film and the other one of the first film and the second film is a conductive film.

13. The film forming method of claim 1, wherein (D) and (E) are repeatedly performed alternately multiple times.

14. A film forming apparatus, comprising:
a processing container;
a holder configured to hold the substrate inside the processing container;
a gas supply mechanism configured to supply gas to an interior of the processing container;
a gas discharge mechanism configured to discharge gas from the interior of the processing container;
a transfer mechanism configured to load or unload the substrate into or from the processing container; and
a controller configured to control the gas supply mechanism, the gas discharge mechanism, and the transfer mechanism to perform the film forming method of claim 1.
